(19) United States
(12) Patent Application Publication
(10) Pub. No.: US 2010/0038689 A1
(43) Pub. Date: Feb. 18, 2010

(54) INTEGRATING FABRICATION OF PHOTODETECTOR WITH FABRICATION OF CMOS DEVICE ON A SILICON-ON-INSULATOR SUBSTRATE

(75) Inventors: Donghwan Ahn, Austin, TX (US); Sanjay Banerjee, Austin, TX (US); Joe C. Campbell, Charlottesville, VA (US)

Correspondence Address: Winstead, P.C., P.O. Box 50784, Dallas, TX, 75201, US

(73) Assignee: Board of Regents, The University of Texas System, Austin, TX (US)

(21) Appl. No.: 12/191,189

(22) Filed: Aug. 13, 2008

(51) Int. Cl. H01L 31/105; H01L 31/18

(52) U.S. Cl. 257/292; 438/34; 257/E21.158; 257/E31.061

(57) ABSTRACT

A method and semiconductor device for integrating the fabrication of a photodetector with the fabrication of a CMOS device on a SOI substrate. The SOI substrate is divided into two regions, a CMOS region and an optical detecting region. After the CMOS device is fabricated in the CMOS region, the optical detecting region is patterned and etched through the top silicon layer and the buried oxide layer to the base silicon layer. The pattern is etched to a depth so that after a material of a photodetector is deposited in the etched pattern, the material grows to the surface level of the SOI substrate. After the formation of a photodetector structure in the optical detecting region, the metallization process is performed on the CMOS device and the photodetector. In this manner, the fabrication of a photodetector is integrated with the fabrication of a CMOS device on the SOI substrate.

### TECHNICAL FIELD

The present invention relates to semiconductor processing, and more particularly to integrating the fabrication of a photodetector with the fabrication of a CMOS device on a Silicon-On-Insulator (“SOI”) substrate.

### BACKGROUND OF THE INVENTION

At present, the vast majority of integrated circuit products are formed on bulk semiconductor wafers. However, Silicon-On-Insulator (“SOI”) wafer-based products are under development as a major technology for the future. SOI refers to the use of a layered silicon-insulator-silicon substrate in place of conventional silicon substrates in semiconductor manufacturing. SOI offers may advantages over the use of bulk silicon.

For example, SOI structures are recognized as an ideal configuration to fabricate Complementary Metal-Oxide-Semiconductor (“CMOS”) transistors. SOI technology offers many advantages to fabricating CMOS devices, such as applying a simpler fabrication sequence and resultant cross-section compared to circuits fabricated on bulk silicon. In addition, the SOI scheme reduces latchup, which is the inadvertent creation of a low-impedance path between the power supply rails of an electronic component, triggering a parasitic structure, which then acts as a short circuit, disrupting proper functioning of the part. SOI further reduces the size and/or increases packing density that will increase the circuit speed.

A photodetector may refer to a device that senses light or other electromagnetic energy. Photodetectors may be fabricated separately from the fabrication of other devices, such as CMOS devices. However, when photodetectors are fabricated separately from the fabrication of other devices, there is an increase in manufacturing costs as well as packaging procedures. Further, there is the required use of wire bonding to integrate the photodetector with the other fabricated device.

If, however, the fabrication of the photodetector could be integrated with the fabrication of the other device, such as a CMOS device, then packaging is reduced. Further, cost is reduced, as instead of using two separate substrates, the photodetector and the other device could use a single substrate. Further, one can take advantage of the economies of scale as the fabrication of the photodetector could use the same silicon process in fabricating the other device, such as a CMOS device. Also, performance is improved as the interconnections will be located on the integrated circuit.

Currently, when a photodetector is fabricated on a silicon substrate, the material of the photodetector (e.g., germanium (“Ge”)) is grown and fabricated on the substrate surface level of a plain silicon bulk wafer. Alternatively, the material of the photodetector (e.g., germanium (“Ge”)) is grown and fabricated on the top silicon layer of the SOI substrate. In order for the photodetector in surface-normal illumination applications (e.g., in fiber-optic applications) to be an efficient optical absorber, the thickness of the material of the photodetector may have to a few micrometers thick. For example, with the absorption coefficient of germanium being 4000 cm⁻¹ for a 1550 nm wavelength, a 2.5 μm Ge layer is required to achieve a 63% quantum efficiency.

In contrast, CMOS devices are sub-surface devices. That is, the Metal-Oxide-Semiconductor Field-Effect Transistor (“MOSFET”) channels, sources and drains of the CMOS devices are formed below the surface level of the silicon wafer or top silicon layer of the SOI substrate. The height of the transistor gate in CMOS devices formed above the substrate surface is very small, such as on the order of being much less than 1 μm.

As a result of requiring a relatively thick layer (e.g., 2.5 μm) of material (e.g., Ge) to construct a photodetector on the substrate surface level, there are structural challenges for integrating the fabrication of a photodetector with the fabrication of CMOS devices on a SOI substrate. Since the height (e.g., 2.5 μm) of the photodetector is much greater than the height (e.g., much less than 1 μm) of the other surface components (e.g., transistor gate) of the CMOS device, many of the standard silicon processing technologies for fabricating CMOS devices, which are largely based on treating planar substrate structures, may experience difficulties. For example, with a disparity in the focus of depth between the photodetector and the CMOS devices, lithography for contacts and other processes (e.g., implantation of impurities in lightly doped regions) will be difficult. For example, standard metallization processing for multi-level interconnects uses chemical mechanical processing which requires a planar substrate surface. As a result, standard interconnection structures for a densely-integrated CMOS integrated circuit would not be able to be obtained with the fabrication of a photodetector on the substrate surface level. Additionally, constructing a photodetector on the same silicon substrate surface as the CMOS devices is difficult because CMOS devices and photodetectors prefer different types of silicon substrate layers.

If, however, the challenges to integrating the fabrication of the photodetector with the fabrication of a CMOS device on a SOI substrate could be overcome, then the CMOS device could be fabricated using the superior SOI technology while at the same time, in connection with fabricating the photodetector, there would be a reduction in packaging and cost as well as an improvement in the performance.

### BRIEF SUMMARY OF THE INVENTION

In one embodiment of the present invention, a method for integrating the fabrication of a photodetector with the fabrication of a Complementary Metal-Oxide-Semiconductor (“CMOS”) device on a Silicon-On-Insulator (“SOI”) substrate comprises fabricating the CMOS device on the SOI substrate, where the SOI substrate comprises a stacking structure of a base silicon layer, a buried oxide layer, and a top silicon layer. The method further comprises placing a protective dielectric layer over the CMOS device after the fabrication of the CMOS device and prior to a metallization process step. Furthermore, the method comprises patterning and etching through the top silicon layer and the buried oxide layer to the base silicon layer in an optical detecting region of the SOI substrate, where the pattern is etched to a depth so that after a material of a photodetector is deposited in the etched pattern, the material grows to a surface level of the SOI substrate. Additionally, the method comprises depositing a buffer layer in the etched pattern. Furthermore, the method comprises depositing an epitaxial layer of the material of the photodetector on the buffer layer in the etched pattern. Further, the method comprises growing the deposited epitaxial layer of the material of the photodetector in the etched pattern in such a manner as to allow the material to grow to the surface level of the SOI substrate. In addition, the method comprises performing the metallization on the CMOS device and the photodetector.

In another embodiment of the present invention, a semiconductor device comprises a CMOS region fabricated on a Silicon-On-Insulator (“SOI”) substrate, where the SOI substrate comprises a stacking structure of a base silicon layer, a buried oxide layer, and a top silicon layer. The CMOS region comprises a p-type Metal-Oxide-Semiconductor Field-Effect Transistor (“MOSFET”) and an n-type MOSFET. Further, the semiconductor device comprises an optical detecting region fabricated on the SOI substrate, where the optical detecting region comprises a photodetector, where an epitaxial layer of material of the photodetector is grown from a buffer layer deposited on the base silicon layer to a substrate surface level of the SOI substrate. The top surface of the photodetector is level with the substrate surface level.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE SEVERAL VIEWS OF THE DRAWING

A better understanding of the present invention can be obtained when the following detailed description is considered in conjunction with the following drawings, in which:

FIG. 1 is a flowchart of a method for integrating the fabrication of a photodetector with the fabrication of a CMOS device on a SOI substrate in accordance with an embodiment of the present invention;

FIGS. 2A-L depict cross-sectional views of a semiconductor device during the fabrication steps described in FIGS. 1 and 3 in accordance with an embodiment of the present invention; and

FIG. 3 is a flowchart of the sub-steps of fabricating a CMOS device on a SOI substrate in the CMOS region in accordance with an embodiment of the present invention.

### DETAILED DESCRIPTION OF THE INVENTION

The present invention comprises a method and semiconductor device for integrating the fabrication of a photodetector with the fabrication of a Complementary Metal-Oxide-Semiconductor (“CMOS”) device on a Silicon-On-Insulator (“SOI”) substrate. In one embodiment of the present invention, the SOI substrate is a stacking structure of a base silicon layer, a buried oxide layer and a top silicon layer. The SOI substrate is divided into two regions, a CMOS region and an optical detecting region. After the CMOS device is fabricated on the SOI substrate in the CMOS region, a protective dielectric layer is placed over the CMOS device prior to the metallization process step. The optical detecting region of the SOI substrate is patterned and etched through the top silicon layer and the buried oxide layer to the base silicon layer of the SOI substrate. The pattern is etched to a depth so that after a material of a photodetector is deposited in the etched pattern, the material grows to the surface level of the SOI substrate. A buffer layer is deposited in the etched pattern. An epitaxial layer of material (e.g., germanium) of the photodetector is deposited on the buffer layer in the etched pattern and grown to the surface level of the SOI substrate. The metallization process is then performed on the CMOS device and the photodetector. In this manner, the fabrication of a photodetector is integrated with the fabrication of a CMOS device on a SOI substrate.

In the following descriptions, well known circuits have been shown in block diagram form, and, for the most part, details considering timing considerations and the like have been omitted in order not to obscure the present inventions in unnecessary detail.

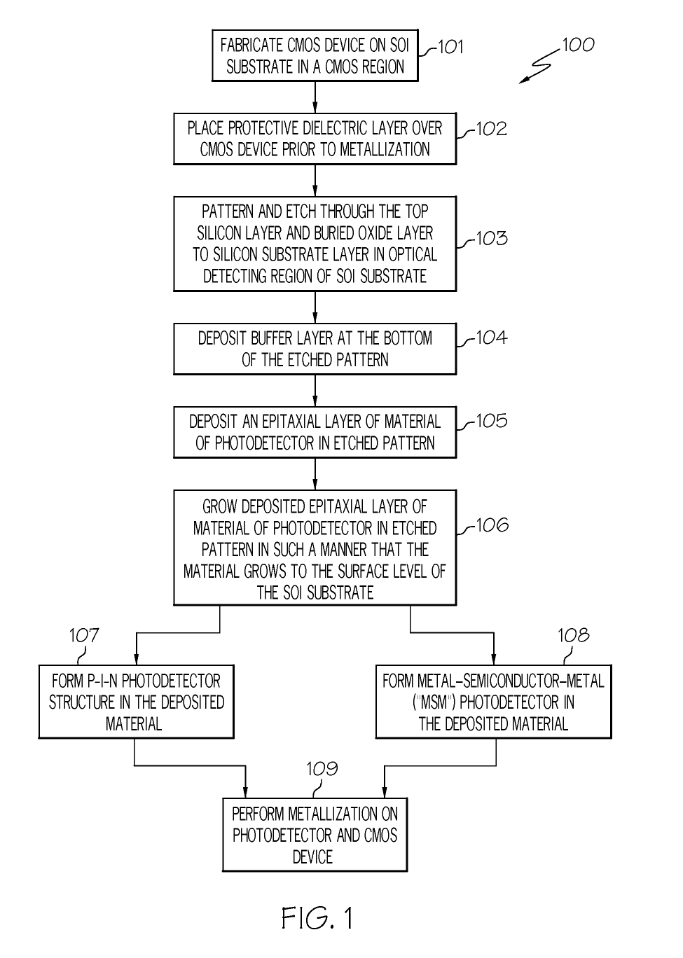

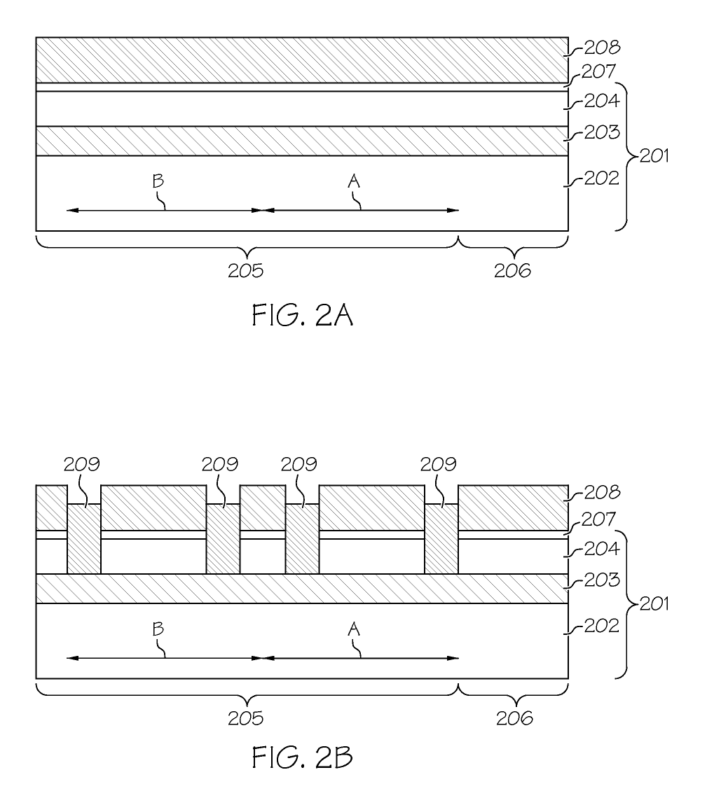

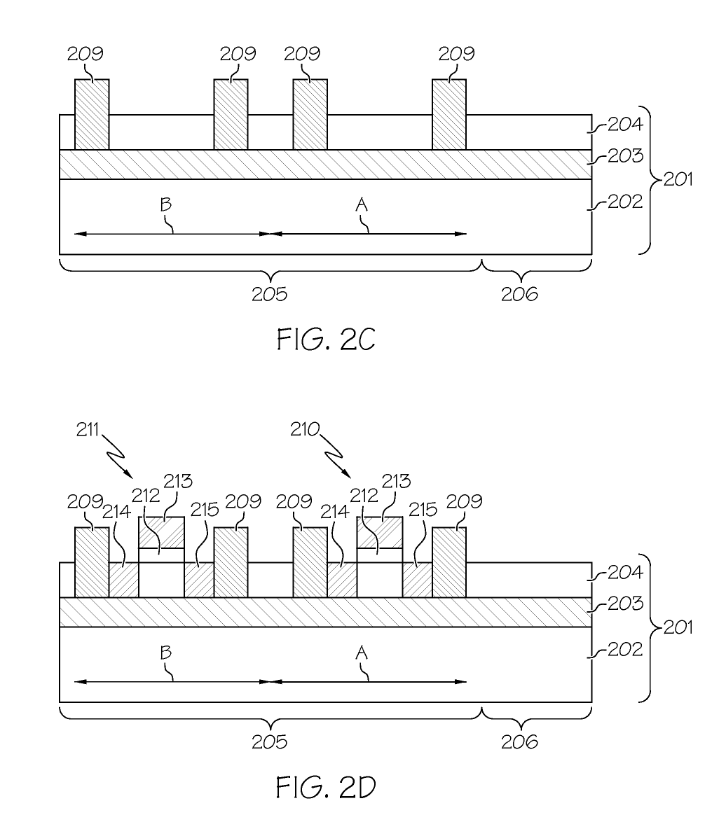

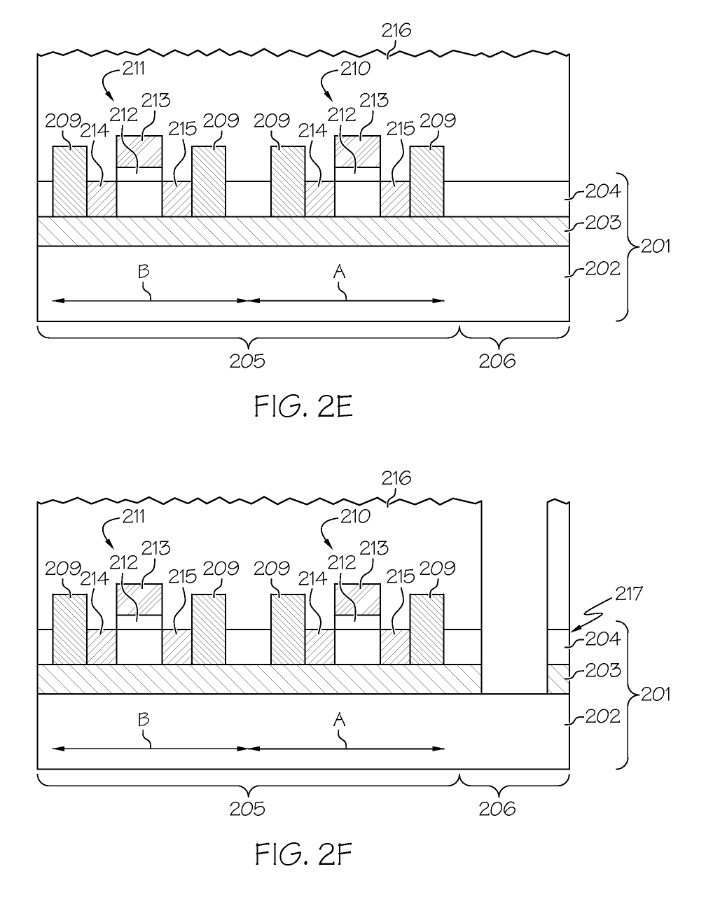

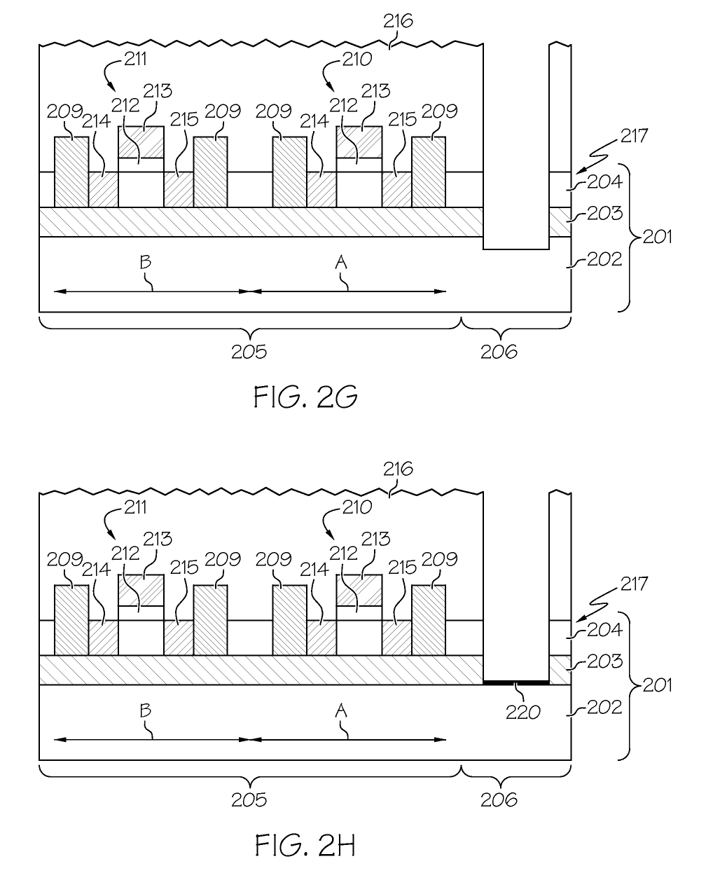

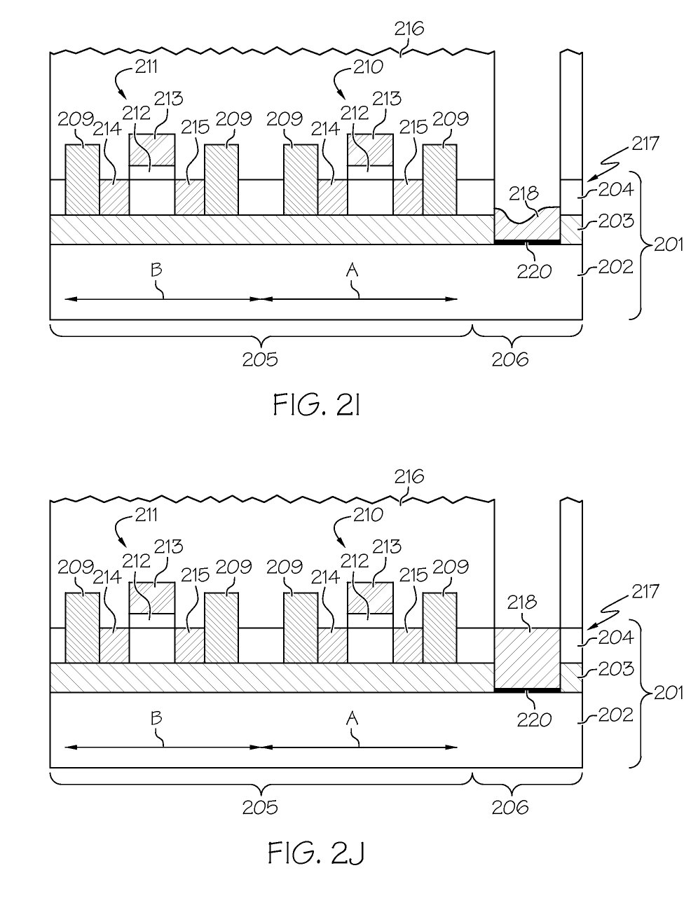

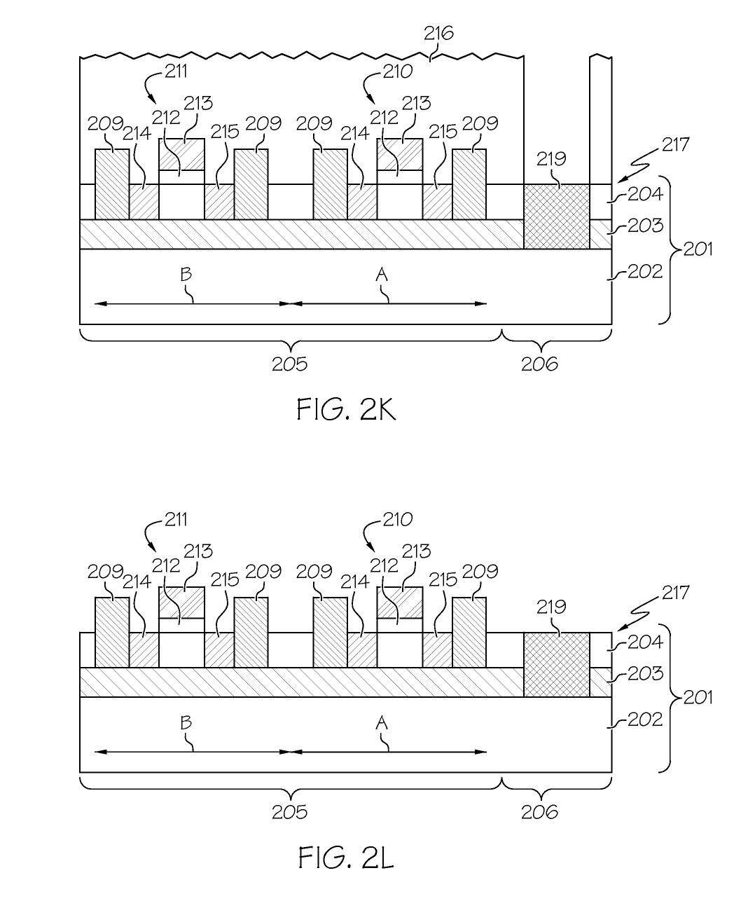

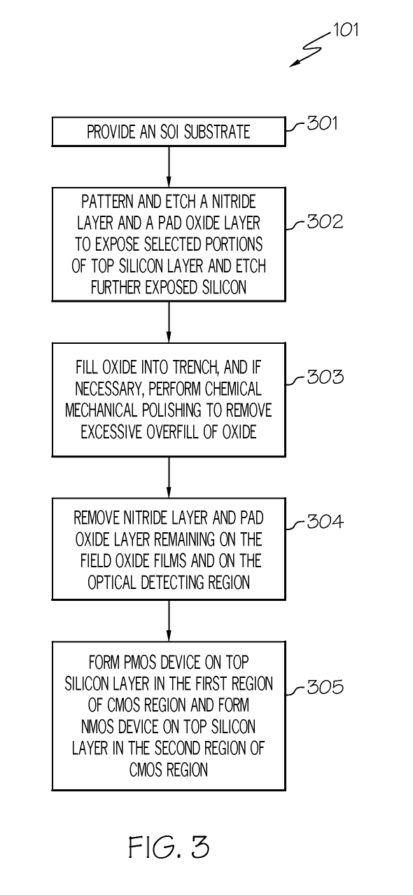

As discussed in the Background section, if the challenges to integrating the fabrication of the photodetector with the fabrication of a CMOS device on a SOI substrate could be overcome, then the CMOS device could be fabricated using the superior SOI technology while at the same time, in connection with fabricating the photodetector, there would be a reduction in packaging and cost as well as an improvement in the performance. The fabrication of a photodetector may be integrated with the fabrication of a CMOS device on a SOI substrate using the principles of the present invention as discussed below in connection with FIGS. 1, 2A-L and 3. FIG. 1 is a flowchart of a method for integrating the fabrication of a photodetector with the fabrication of a CMOS device on a SOI substrate. FIG. 3 is a flowchart of the sub-steps of fabricating a CMOS device on a SOI substrate in the CMOS region. FIGS. 2A-L depict cross-sectional views of a semiconductor device during the fabrication steps described in FIGS. 1 and 3.

FIG. 1 is a flowchart of a method 100 for integrating the fabrication of a photodetector with the fabrication of a CMOS device on a SOI substrate in accordance with an embodiment of the present invention. FIG. 1 will be discussed in conjunction with FIGS. 2A-L, which depict cross-sectional views of a semiconductor device during the fabrication steps described in FIG. 1 in accordance with an embodiment of the present invention.

Referring to FIG. 1, in conjunction with FIGS. 2A-K, in step 101, a CMOS device is fabricated on a SOI substrate in a CMOS region. There are many processes in fabricating a CMOS device on a SOI substrate. The principles of the present invention are not to be constrained to using any particular process in fabricating a CMOS device on a SOI substrate. An example of one process that may be used to fabricate a CMOS device on a SOI substrate is discussed below in connection with FIG. 3. FIG. 3 is a flowchart of the sub-steps of step 101 of method 100 for fabricating a CMOS device on a SOI substrate in the CMOS region in accordance with an embodiment of the present invention. FIG. 3 will be discussed in connection with FIGS. 2A-D to help understand the steps involved in fabricating a CMOS device on a SOI substrate in the CMOS region.

Referring to FIG. 3, in conjunction with FIGS. 2A-D, in step 301, an SOI substrate 201 is provided as illustrated in FIG. 2A. As further illustrated in FIG. 2A, SOI substrate 201 has a stacking structure that includes a base silicon layer 202 as a means for supporting, and a top silicon layer 204 in which a device is to be formed later, and a buried oxide layer 203 which is sandwiched between base silicon layer 202 and top silicon layer 204. Furthermore, SOI substrate 201 is divided into two regions, a CMOS region 205 and an optical detecting region 206. FIG. 3 is a discussion of the steps in forming a CMOS device(s) in CMOS region 205. A discussion of forming a photodetector in optical detecting region 206 is provided further below in connection with steps 102-109 of FIG. 1.

Returning again to FIG. 2A, in conjunction with step 301 of FIG. 3, CMOS region 205 is divided into two sub-regions, where a p-type Metal-Oxide-Semiconductor Field-Effect Transistor (“MOSFET”) is formed in region A and an n-type MOSFET is formed in region B. Also, in step 301, a pad oxide layer 207 and a nitride layer 208 are formed on the top layer of silicon 204 across both CMOS region 205 and optical detecting region 206.

In step 302, nitride layer 208 and pad oxide layer 207 are patterned to expose selected portions of top silicon layer 204 disposed in regions A and B of CMOS region 205 of SOI substrate 201 as illustrated in FIG. 2B. Further, as illustrated in FIG. 2B, field oxide films 209 are formed by applying thermal oxidation to the exposed portions of top silicon layer 204. Herein, the field oxide films 209 are in contact with the buried oxide layer 203 by controlling temperature of the thermal oxidation process and its process time.

In step 303, oxide is filled into the trench, and if necessary, chemical mechanical polishing is performed to remove excessive overfill of oxide. In step 304, nitride layer 208 and pad oxide layer 207 remaining on the field oxide films 209 and on optical detecting region 204 are removed as illustrated in FIG. 2C.

In step 305, according to known semiconductor processes, a p-type MOS device 210 is formed on top silicon layer 204 of region A being defined by field oxide films 209 and an n-type MOS device 211 is formed on top silicon layer 204 of region B being defined by field oxide films 209 as illustrated in FIG. 2D. As further illustrated in FIG. 2D, p-type MOS device 210 and n-type MOS device 211 include a gate oxide layer 212, a gate electrode 213 and source and drain regions 214, 215.

Method 300 may include other and/or additional steps that, for clarity, are not depicted. Further, method 300 may be executed in a different order presented and that the order presented in the discussion of FIG. 3 is illustrative. Additionally, certain steps in method 300 may be executed in a substantially simultaneous manner or may be omitted.

In one embodiment, after the fabrication of a CMOS device in CMOS region 205 but prior to back end processing, such as metallization, a photodetector is fabricated on SOI substrate 201 using the process as discussed in steps 102-109 of FIG. 1.

Returning to FIG. 1, in conjunction with FIGS. 2E-L, in step 102, prior to metallization, a protective dielectric layer 216 (e.g., silicon dioxide (SiO₂), silicon oxynitride (SiOₓN_{y}), silicon nitride (SiN)) is placed over CMOS device (p-type MOS device 210 and n-type MOS device 211) as well as over optical detecting region 206 as illustrated in FIG. 2E.

In step 103, a pattern is etched through protective layer 216, top silicon layer 204 and buried oxide layer 203 in optical detecting region 206 to silicon substrate layer 202 where a photodetector is to be fabricated as illustrated in FIG. 2F. In one embodiment, a pattern is etched to a particular depth so that after a material (e.g., germanium (Ge), Silicon germanium (SiₓGe₁₋ₓ), gallium arsenide (GaAs)) of a photodetector is deposited in the etched pattern, the material grows to a surface level 217 (illustrated in FIG. 2F) of SOI substrate 201. For example, the pattern may be etched to the barrier of the buried oxide layer 203 and base silicon layer 202 as illustrated in FIG. 2F. In another example, the pattern may be over-etched by etching into a portion of the base silicon layer 202 as illustrated in FIG. 2G.

While the following description describes the steps following the etching of the pattern to the barrier of the buried oxide layer 203 and base silicon layer 202 as illustrated in FIG. 2F, it is noted that the principles of the present invention as discussed in steps 104-109 will apply to the pattern etched as shown in FIG. 2G.

In step 104, a buffer layer 220, where the buffer layer may consist of material that is the same or different from the photodetector material, is deposited at the bottom of the etched pattern as shown in FIG. 2H.

In step 105, an epitaxial layer 218 of the material (e.g., germanium (Ge), Silicon. germanium (SiₓGe₁₋ₓ), gallium arsenide (GaAs)) of the photodetector is deposited on buffer layer 220 in the etched pattern as illustrated in FIG. 21. The principles of the present invention may be applied to any material to be used to form a photodetector that is compatible with silicon and that detects the appropriate wavelength in question. For example, the material of the photodetector may be germanium. In another example, the material of the photodetector may be a Ill-V compound semiconductor material, such as gallium arsenide.

In step 106, the deposited epitaxial layer 218 of the material (e.g., germanium (Ge), gallium arsenide (GaAs)) in the etched pattern of the photodetector is grown in such a manner as to allow the material to grow to surface level 217 of SOI substrate 201 as illustrated in FIG. 2J. In one embodiment, chemical vapor deposition is used to deposit and grow the epitaxial layer 218.

In step 107, a p-i-n photodetector structure (illustrated in FIG. 2K as element 219) is formed in the deposited material of the photodetector. In one embodiment, the p-i-n photodetector structure formed is a later p-i-n photodetector. A lateral p-i-n photodetector is formed by implanting a p-type implant on one electrode and implanting an n-type implant on another electrode. It is known in the art how to form a lateral p-i-n photodetector structure, and, as a result, will not be discussed in detail for the sake of brevity.

In another embodiment, the p-i-n photodetector structure formed is a vertical p-i-n photodetector. A vertical p-i-n photodetector structure may be formed when an n-type implanted region and a top contact are, aligned to a heavily-doped p-type region created before the growth of the epitaxial layers. The bottom contact may be made by etching down to and into the substrate. It is known in the art how to form a vertical p-i-n photodetector structure, and, as a result, will not be discussed in detail for the sake of brevity.

While the previous description discusses a p-i-n photodetector structure, it is noted that the principles of the present invention would cover an n-i-p photodetector structure.

Alternatively to step 107, in step 108, a metal-semiconductor-metal photodetector structure (illustrated in FIG. 2K as element 219) is formed in the deposited material of the photodetector. A metal-semiconductor-metal photodetector structure is a photodetector device containing two Schottky contacts (i.e., two metallic electrodes on a semiconductor material) in contrast to a p-n junction. It is known in the art how to form a metal-semiconductor-metal photodetector structure, and, as a result, will not be discussed in detail for the sake of brevity.

It is noted for clarity that other different photodetector structures may be formed in the deposited material and that the principles of the present invention are not to be limited to forming any one particular type of photodetector structure.

Upon the formation of a photodetector structure in step 107 or 108, in step 109, a metallization is performed on the CMOS device (p-type MOS device 210 and n-type MOS device 211) and photodetector 219 resulting in the structure depicted in FIG. 2L. The details (e.g., metal contacts/pads, passivation oxide layer) of the metallization step are known in the art and are not shown in FIG. 2L for ease of understanding.

As a result of implementing method 100, the fabrication of a photodetector is integrated with the fabrication of a CMOS device on a SOI substrate. Further, as a result of fabricating the photodetector based on the base silicon layer 202 as discussed above, different specifications may be used to form photodetector 219 in optical detecting region 206 than the specifications used to form CMOS devices 210, 211 in CMOS region 205. For example, a vertical p-i-n germanium photodetector may be formed easily on highly doped p+ or n+ wafers; whereas, NMOSFET/PMOSFET devices may be preferred to be formed on lightly-doped wafers. By implementing method 100, these different specifications may both be satisfied.

Method 100 may include other and/or additional steps that, for clarity, are not depicted. Further, method 100 may be executed in a different order presented and that the order presented in the discussion of FIG. 1 is illustrative. Additionally, certain steps in method 100 may be executed in a substantially simultaneous manner or may be omitted.

Although the method and semiconductor device are described in connection with several embodiments, it is not intended to be limited to the specific forms set forth herein, but on the contrary, it is intended to cover such alternatives, modifications and equivalents, as can be reasonably included within the spirit and scope of the invention as defined by the appended claims.

1. A method for integrating the fabrication of a photodetector with the fabrication of a Complementary Metal-Oxide-Semiconductor (“CMOS”) device on a Silicon-On-Insulator (“SOI”) substrate, the method comprising:
fabricating said CMOS device on said SOI substrate, wherein said SOI substrate comprises a stacking structure of a base silicon layer, a buried oxide layer, and a top silicon layer;
placing a protective dielectric layer over said CMOS device after said fabrication of said CMOS device and prior to a metallization process step;
patterning and etching through said top silicon layer and said buried oxide layer to said base silicon layer in an optical detecting region of said SOI substrate, wherein said pattern is etched to a depth so that after a material of a photodetector is deposited in said etched pattern, said material grows to a surface level of said SOI substrate;
depositing a buffer layer in said etched pattern;
depositing an epitaxial layer of said material of said photodetector on said buffer layer in said etched pattern;
growing said deposited epitaxial layer of said material of said photodetector in said etched pattern in such a manner as to allow said material to grow to said surface level of said SOI substrate; and
performing said metallization on said CMOS device and said photodetector.

2. The method as recited 1 further comprising:
forming a p-i-n photodetector structure in said optical detecting region after said deposited epitaxial layer of said material of said photodetector is grown to said surface level of said SOI substrate.

3. The method as recited 1 further comprising:
forming an n-i-p photodetector structure in said optical detecting region after said deposited epitaxial layer of said material of said photodetector is grown to said surface level of said SOI substrate.

4. The method as recited in claim 1 further comprising:
forming a metal-semiconductor-metal photodetector structure in said optical detecting region after said deposited epitaxial layer of said material of said photodetector is grown to said surface level of said SOI substrate.

5. The method as recited in claim 1, wherein said material of said photodetector comprises germanium.

6. The method as recited in claim 1, wherein said material of said photodetector comprises III-V compound semiconductor material.

7. The method as recited in claim 1, wherein said material of said photodetector is compatible with silicon.

8. The method as recited in claim 1, wherein said pattern is etched to a barrier of said buried oxide layer and said base silicon layer.

9. The method as recited in claim 1, wherein said pattern is over-etched into a portion of said base silicon layer.

10. A semiconductor device, comprising:
a CMOS region fabricated on a Silicon-On-Insulator (“SOI”) substrate, wherein said SOI substrate comprises a stacking structure of a base silicon layer, a buried oxide layer, and a top silicon layer, wherein said CMOS region comprises:
a p-type Metal-Oxide-Semiconductor Field-Effect Transistor (“MOSFET”); and
an n-type MOSFET; and
an optical detecting region fabricated on said SOI substrate, wherein said optical detecting region comprises a photodetector, wherein an epitaxial layer of material of said photodetector is grown from a buffer layer deposited on said base silicon layer to a substrate surface level of said SOI substrate, wherein a top surface of said photodetector is level with said substrate surface level.

11. The semiconductor device as recited in claim 10, wherein said photodetector comprises a p-i-n photodetector structure.

12. The semiconductor device as recited in claim 10, wherein said photodetector comprises an n-i-p photodetector structure.

13. The semiconductor device as recited in claim 10, wherein said photodetector comprises a metal-semiconductor-metal photodetector structure.

14. The semiconductor device as recited in claim 10, wherein said material of said photodetector comprises germanium.

15. The semiconductor device as recited in claim 10, wherein said material of said photodetector comprises III-V compound semiconductor material.

16. The semiconductor device as recited in claim 10, wherein said material of said photodetector is compatible with silicon.

17. The semiconductor device as recited in claim 10, wherein said epitaxial layer of material of said photodetector is grown from said buffer layer located at a barrier of said buried oxide layer and said base silicon layer.

18. The semiconductor device as recited in claim 10, wherein said epitaxial layer of material of said photodetector is grown from said buffer layer located within a portion of said base silicon layer.
